(19) United States
(12) Patent Application Publication
(10) Pub. No.: US 2004/0119455 A1
(43) Pub. Date: Jun. 24, 2004

(54) Method for testing parameters of high speed data signals

(76) Inventor: Stephen K. Sunter, Nepean (CA)

Correspondence Address: LOGICVISION (CANADA), INC., 1565 CARLING AVENUE, SUITE 508, OTTAWA, ON, K1Z 8R1, CA

(21) Appl. No.: 10/724,193

(22) Filed: Dec. 1, 2003

Related U.S. Application Data
(60) Provisional application No. 60/433,988, filed on Dec. 18, 2002.

(51) Int. Cl. H03D 13/00; G01R 25/00

(52) U.S. Cl. 324/76.77

(57) ABSTRACT

A method for deducing parameters of high frequency data signals, comprises generating high frequency data signals using predetermined data sequences; measuring average voltage of each of the data signals; and deducing the parameters from the measured average voltages.

### CROSS-REFERENCE TO RELATED APPLICATIONS

This application claims the benefit of U.S. Provisional Patent Application Serial No. 60/433,988 filed Dec. 18, 2002.

### BACKGROUND OF THE INVENTION

1. Field of the Invention

The present invention relates, in general, to the testing of integrated circuits, more specifically, to testing parameters of high frequency data signals using low frequency measurements.

2. Description of Related Art

As the data rate of IC pins increases each year, it is becoming increasingly more difficult to measure signal parameters to determine whether integrated circuits which generate high speed data signals pass or fail as well as increasingly more important to develop test methods that do not require a tester to operate at the high data rates being tested. A standard entitled “IEEE Standard for a Mixed Signal Test Bus”, was published in 1999 by the IEEE, and is known as IEEE Std. 1149.4-1999, or simply 1149.4. The general architecture of an IC designed according to 1149.4 is shown in FIG. 1. FIG. 1 illustrates a circuit 10 having analog and digital circuits connected to pins 12 by means of analog boundary modules 14. A portion of a boundary scan module for an individual pin is shown in FIG. 2. Analog buses AB1 and AB2 connect to each module 14 and are accessible via access pins AT1 and AT2 and Test Bus Interface Circuit 16. This analog test bus was primarily designed to permit the low frequency measurement of discrete passive components, including capacitors and resistors, that are connected to the pins of ICs.

The typical way of improving the signal integrity of a transmission line is to terminate it with an impedance R_{L} equal to the characteristic impedance of the transmission line. FIG. 3 illustrates various prior art differential driver termination arrangements. FIG. 3A is a schematic of a DC-coupled differential driver and receiver with termination resistor. FIG. 3B illustrates a DC-coupled differential driver and receiver with termination and bias resistors. FIG. 3C shows a DC-coupled differential driver and two single-ended receivers, with termination and bias resistors.

In the case of differential signals, the termination resistor is typically connected between the differential signals and has a value equal to twice the characteristic impedance (of typically 50 ohms) of individual transmission lines. The voltage swings on each wire of a differential pair, for various standard differential signals, are typically between 200 and 500 millivolts.

Accurately measuring the voltage swing for these signals, when they have data rates exceeding 1 Gbit/sec can be difficult, particularly since simply accessing these signals can affect their amplitude. Because of these measuring difficulties, a conventional method of testing circuits which transmit or receive high frequency signals is simply to confirm that a signal is being transmitted or received. However, a circuit may be defective even though the circuit may “pass” this test. There is a need for a method which facilitates the measurement of parameters of such signals.

### SUMMARY OF THE INVENTION

The present invention seeks to provide a method for parametrically testing several parameters of data signals, including single-ended and differential high frequency data (for example, higher than 1 Gb/s) signals, using only low frequency digital and analog test circuitry. The present invention also seeks to provide signal delivery in a way that is compatible with the IEEE 11149.4 test access standard.

The method of the present invention is generally defined as a method for deducing parameters of data signals, comprising the steps of generating high frequency data signals using predetermined data sequences; measuring average voltage of each of the data signals; and deducing the parameters from the measured average voltages.

The present invention is not limited to high frequency data signals, but can also be used to deduce parameters of low frequency signals.

Embodiments of the method invention measure four parameters of a high frequency data signal, determine the average (DC) voltage for each of four different data patterns to deduce logic 0 and logic 1 voltages, and rise and fall transition times. The method and circuitry can be used for differential and single-ended signals.

### BRIEF DESCRIPTION OF THE DRAWINGS

These and other features of the invention will become more apparent from the following description in which reference is made to the appended drawings in which:

FIG. 1 is an architectural schematic of a prior art 1149.4-compliant IC;

FIG. 2 is a schematic of a portion of a typical prior art 1149.4 boundary module and of a portion of a test bus interface circuit (TBIC);

FIG. 3A is a schematic of a prior art DC-coupled differential driver and receiver with termination resistor;

FIG. 3B is a schematic of a prior art DC-coupled differential driver and receiver, with termination and bias resistors;

FIG. 3C is a schematic of a prior art DC-coupled differential driver and two single-ended receivers, with termination and bias resistors;

FIG. 4 is a schematic of a circuit that includes resistors for low frequency access to the output of a high frequency transmitter;

FIG. 5 is a schematic of a circuit that includes transistors for low frequency access to the output of a high frequency transmitter;

FIG. 6A is a waveform of a transmitter output signal, showing a realistic version (top solid line) and a piecewise linear approximation (dashed line), and the complementary signal (bottom solid line) of a differential pair;

FIG. 6B is a waveform of a transmitter output signal, showing a realistic version that has overshoot (solid line) and a piecewise linear approximation (dashed line);

FIG. 7 shows various waveforms that can be used to implement tests according to an embodiment of the present invention; and

FIG. 8 is a schematic of an AC-coupled differential driver and receiver, with miscellaneous passive components and low frequency test access transistors, according to an embodiment of the present invention.

### DETAILED DESCRIPTION OF EMBODIMENTS OF THE INVENTION

In the following detailed description, numerous specific details are set forth in order to provide a thorough understanding of the present invention, However, it will be understood by those skilled in the art that the present invention may be practiced without these specific details. In other instances, well known methods, procedures, components and circuits have not been described in detail so as not to obscure aspects of the present invention.

An objective of the invention is to test AC parameters of a high speed signal while only measuring DC voltages. The present invention provides a method for deducing parameters of data signals which can be used for both low and high frequency data signals. The method comprises generating data signals using predetermined data sequences; measuring average voltage of each of the data signals; and deducing the parameters from the measured average voltages.

Referring to FIG. 4, the average voltage of the signals at the high frequency differential transmitter driver 20 is accessed via resistors R_{A} connected to the driver. Resistors R_{A} serve two purposes: isolation to prevent transmission line effects, and low pass filtering when the resistors are connected to a capacitance. A low frequency voltmeter (not shown) that measures DC voltage is connected to the resistors. Filtering capacitors 22, shown in dofted lines, may also be connected to the resistors. The average voltage of a data signal is dependent on the proportion of 1's and 0's, and on the shape of the rising and falling edges of the waveform. Termination resistor R_{L} may or may not be connected—its presence will greatly affect the measured values, as is well known.

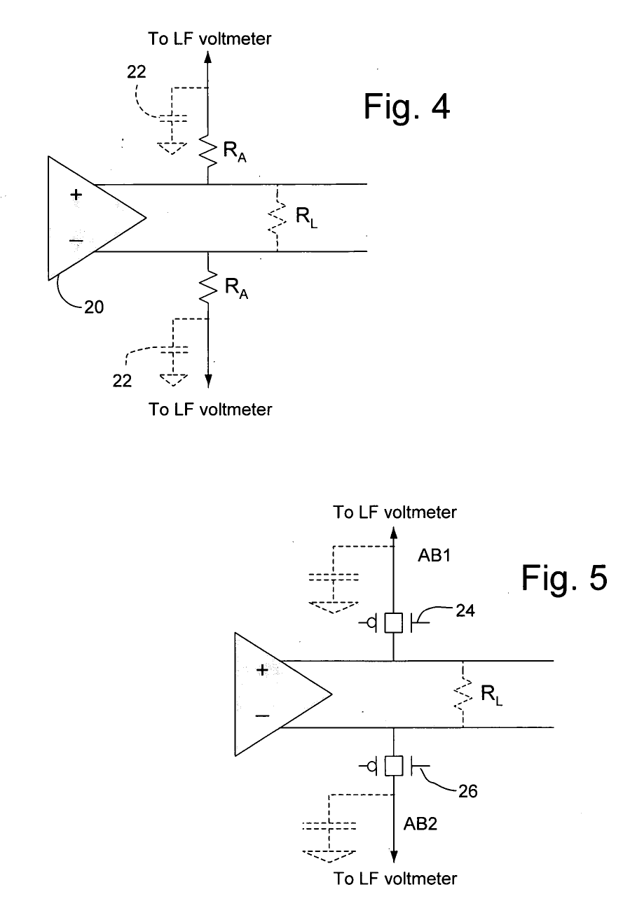

FIG. 5 shows how high speed signals can be accessed via transistors 24 and 26 that are enabled by logic gates and which form part of an analog boundary module (not shown), connected to internal analog buses AB1 and AB2 of a circuit, according to the 1149.4 standard.

In a specific embodiment of the present invention, the parameters are waveform amplitude, i.e., the difference between two logic levels; the difference between effective rise and fall transition times; and, rise and fall transition times.

In the embodiment for determining waveform amplitude, the step of measuring average voltage comprises (a) measuring average voltage for a periodic pattern containing a number of consecutive same-value logic values; and (b) measuring average voltage for a pattern containing a different number of consecutive same-value logic values; and the step of deducing parameters comprises (c) performing a calculation based on the measured average voltages.

In the embodiment for deducing the difference between effective rise and fall transition times, the step of measuring average voltage comprises (a) measuring average voltage for a periodic pattern containing a number of consecutive same-value logic values and (b) measuring average voltage for a pattern in which the number of consecutive same-value logic values are split into two or more groups of same-value logic values; and, again, the step of deducing parameters involves (c) performing a calculation based on measured average voltages.

In the embodiment for deducing rise and fall transition times, the step of measuring average voltage comprises (a) measuring average voltage for a periodic pattern containing a number of consecutive same-value logic values; (b) measuring average voltage for a pattern containing a different number of consecutive same value logic values; (c) measuring average voltage for a pattern in which the number of consecutive same-value logic values is split into two or more groups of same-value logic values; and (d) measuring average voltage for a pattern containing one or more isolated logic values surrounded by the opposite logic value; and the step of deducing parameters comprises (e) performing a calculation based on measured average voltages.

These methods can be used for testing digital circuit and analog circuits and as well as to determine circuit gain or frequency response by comparing deduced logic voltages and rise and fall time values of a circuit output signal to deduced logic voltages and rise and fall time values of a circuit input signal.

The bit patterns or data sequences that can be transmitted are typically easily programmed, although sometimes a coding scheme places restrictions on transmitted patterns. For example, the standard 8b10b coding scheme converts 8-bit data words into 10-bit words in which the number of consecutive same-value bits is limited to five, and the number of ones in any sequence of 20 bits is always 10, to minimize the variation in the average voltage of the signal. This encoding should be disabled to perform the measurements described in the present invention. Some encoding schemes may need to be disabled to obtain the desired bit sequence to be transmitted. For example, a randomizing coding such as a cyclic redundancy code (CRC) should be disabled for this test.

The above embodiments will now be described more fully by way of the following examples.

Procedure for Measuring Waveform Amplitude

The following is the test procedure for measuring at-speed logic voltage levels, using the circuit of FIG. 4 or FIG. 5.

First, while the driver is transmitting a periodic pattern containing M logic 1's and at least one sequence of consecutive 1's within each N-bit period, measure the average output voltage, V_{1avg}, single-ended or differentially, via access resistors R_{A}.

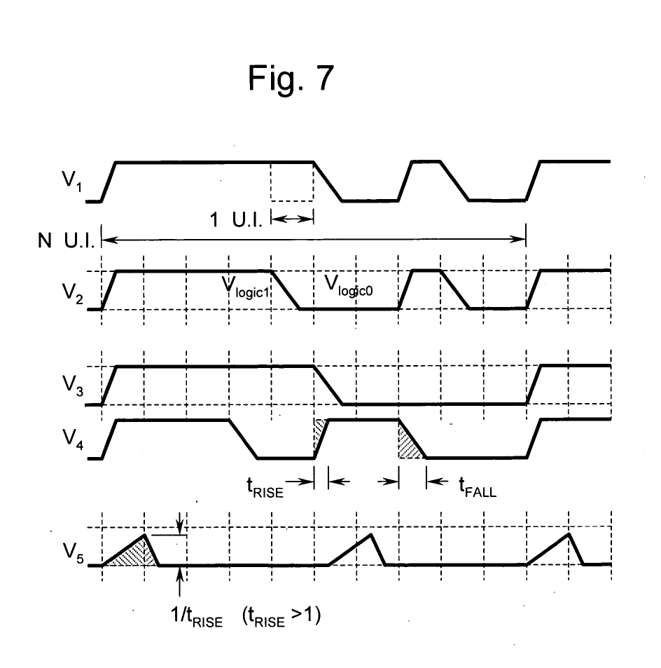

For example, for M₁=6 and a 10-bit period, the transmitted logic bits could be 1111100010 (five consecutive 1's, but six 1's in total per period), as shown for V₁ of FIG. 7. If the single-ended logic 1 voltage is 1.4 volts and the logic 0 voltage is 1.2 volts, then the average voltages measured will be:

for the non-inverted signal:

$$\begin{matrix}{V}_{1 avg +} = {V}_{logic0} + ( {V}_{logic1} - {V}_{logic0} ) \times M / N \\ = 1.2 + ( 1.4 - 1.2 ) \times 0.6 = 1.32 volts\end{matrix}$$

for the inverted signal:

$$\begin{matrix}{V}_{1 avg -} = {V}_{logic0} + ( {V}_{logic1} - {V}_{logic0} ) \times ( N - M ) / N \\ = 1.2 + ( 1.4 - 1.2 ) \times 0.4 = 1.28 volts\end{matrix}$$

for the differential signal:

V_{1avgDiff}=(V₁₊−V₁₋)=0.04V

Second, repeat step 1, for the same pattern except that the first or last 1 in the sequence of consecutive 1's is changed to a 0, so that M₂=M₁−1.

For the 10-bit example, the bit sequence could be 1111000010, as shown for V₂ of FIG. 7, and the average voltages measured would be:

for the non-inverted signal:

V_{2avg+}=1.2+(1.4−1.2)×5/10=1.30 volts;

for the inverted signal:

V_{2avg-}1.2+(1.4−1.2)×5/10=1.30 volts

for the differential signal:

V_{2avgDiff}=0.00V

Third, calculate the value of (V_{logic1}−V_{logic0}).

For an N bit period, the difference between the two average voltages, V₁ and V₂, is equal to the shaded area of V₁ shown in FIG. 7. The height is (V_{logic1}−V_{logic0}), and the width of this area is M₂−M₁ unit intervals per N unit intervals. Therefore,

V₂−V₁=(V_{logic1}−V_{logic0})*(M₂−M₁)/N

Therefore,

V_{logic1}−V_{logic0}=N×(V_{2avg}−V_{1avg})/(M₂−M₁).

V_{logic1} is the steady-state logic 1 voltage for the high speed waveform—this will typically differ from the voltage that would be transmitted if the transmitter delivered a steady-state logic 1 for a long period of time (for example, for milliseconds). V_{logic0} is similarly the logic 0 voltage. For the 10-bit example (N=10, and M₂−M₁=1):

for the non-inverted signal:

$$\begin{matrix}{V}_{logic1 +} = {V}_{logic0 +} = N ( {V}_{2 avg +} - {V}_{1 avg +} ) / ( {M}_{2} - {M}_{1} ) \\ = 10 \times ( 1.30 - 1.32 ) / 1 = - 0.2 V\end{matrix}$$

for the inverted signal:

$$\begin{matrix}{V}_{logic1 -} = {V}_{logic0 -} = N ( {V}_{2 avg -} - {V}_{1 avg -} ) / ( {M}_{2} - {M}_{1} ) \\ = 10 \times ( 1.30 - 1.28 ) / 1 = 0.2 V\end{matrix}$$

for the differential signal, which is also equal to the difference between the two single-ended amplitude results:

$$\begin{matrix}{V}_{logic1Diff} = {V}_{logic0Diff} = N ( {V}_{2 avgDiff} - {V}_{1 avgDiff} ) / ( {M}_{2} - {M}_{1} ) \\ = 10 \times ( 0.2 - ( - 0.2 ) ) / 1 = 0.4 V .\end{matrix}$$

In general, average voltages can be measured for the single-ended signals and then subtracted to derive the differential result, or the voltages can be measured differentially, because noise is filtered out (by definition), in either case. The calculated values will be accurate if rise and fall transition times are less than the duration of the sequence of 1's, and for any transition time asymmetry. The bit sequences may be separated into groups, but only if the duration of the group whose length is decreased by one is always longer than either transition time.

Procedure for Measuring Waveform Asymmetry (Difference Between Rise and Fall Times)

The following is the test procedure for measuring the difference between the rise and fall times, using the circuit of FIG. 4 or FIG. 5:

First, while the driver is transmitting a periodic N-bit pattern containing a total of M logic 1's, with G₁ groups of consecutive logic 1's, separated by logic 0's, measure the average output voltage V_{3avg}, via access resistors R_{A}.

For example, for a 10 bit period with one group, the transmitted logic bits could be 1111100000, as shown for V₃ of FIG. 7; if the single-ended logic 1 voltage is 1.4 volts, the logic 0 voltage is 1.2 volts, the rise time is 0.25 Unit Intervals (UI), and the fall time is 0.5 UI, then the average voltages measured would be:

$$\begin{matrix}{V}_{3 avg} = {V}_{logic0} + ( {V}_{logic1} - {V}_{logic0} ) ( M - {G}_{1} ( {t}_{RISE} - {t}_{FALL} ) / 2 ) / N \\ = 1.2 + ( 1.4 - 1.2 ) ( 5 - 1 ( 0.25 - 0.5 ) / 2 ) / 10 \\ = 1.3025 volts\end{matrix}$$

Second, while the driver is transmitting a periodic pattern containing the same number of logic 1's as in the first step, but in G₂ groups of consecutive logic 1's, separated by logic 0's, measure average output voltage V_{4avg}, via access resistors R_{A}.

The number of logic 1's in each of the G₂ groups does not need to be the same, but the duration of each group of 1's and 0's must be longer than the expected transition times.

For example, for a 10 bit period with two pairs of transitions, the transmitted logic bits could be 1110011000, as shown for V₄ of FIG. 7. For the same logic voltages and transition times as in step 1, the average voltages measured would be:

$$\begin{matrix}{V}_{4 avg} = {V}_{logic0} + ( {V}_{logic1} - {V}_{logic0} ) ( M - {G}_{2} ( {t}_{RISE} - {t}_{FALL} ) / 2 ) / N \\ = 1.2 + ( 1.4 - 1.2 ) ( 5 - 2 ( 0.25 - 0.5 ) / 2 ) / 10 \\ = 1.3050 volts .\end{matrix}$$

Third, calculate the values for (t_{RISE}−t_{FALL}), V_{logic1} and V_{logic0}.

For an N bit period, the difference between the two average voltages, V₄ and V₃, is equal to the difference between the two shaded areas of V₄ shown in FIG. 7. The height of both triangles is (V_{logic1}−V_{logic0}), the width of the rise shaded triangle area is t_{RISE} UI per N unit intervals, and its area is (V_{logic1}−V_{logic0})t_{RISE}/2; the width of the fall shaded triangle is t_{FALL} UI per N unit intervals, and its area is (V_{logic1}−V_{logic0})t_{FALL}/2. Therefore,

V_{4avg}−V_{3avg}=(G₂−G₁)×[(V_{logic1}−V_{logic0})t_{FALL}/(2N)−(V_{logic1}−V_{logic0})t_{RISE}/(2N)]

Therefore,

t_{RISE}−t_{FALL}=2N(V_{3avg}−V_{4avg})/((V_{logic1}−V_{logic0})(G₂−G₁)),

where the value of (V_{logic1}−V_{logic0}) is determined using the previous procedure. Note that (t_{RISE}−t_{FALL}) may have a negative value.

For the 10-bit example,

$$\begin{matrix}{t}_{RISE} - {t}_{FALL} = 2 N ( {V}_{3 avg} - {V}_{4 avg} ) / ( ( {V}_{logic1} - {V}_{logic0} ) ( {G}_{2} - {G}_{1} ) ) \\ {t}_{RISE} - {t}_{FALL} = 2 \times 10 \times ( 1.3025 - 1.3050 ) / ( ( 0.2 ) ( 2 - 1 ) ) \\ = - 0.25 UI\end{matrix}$$

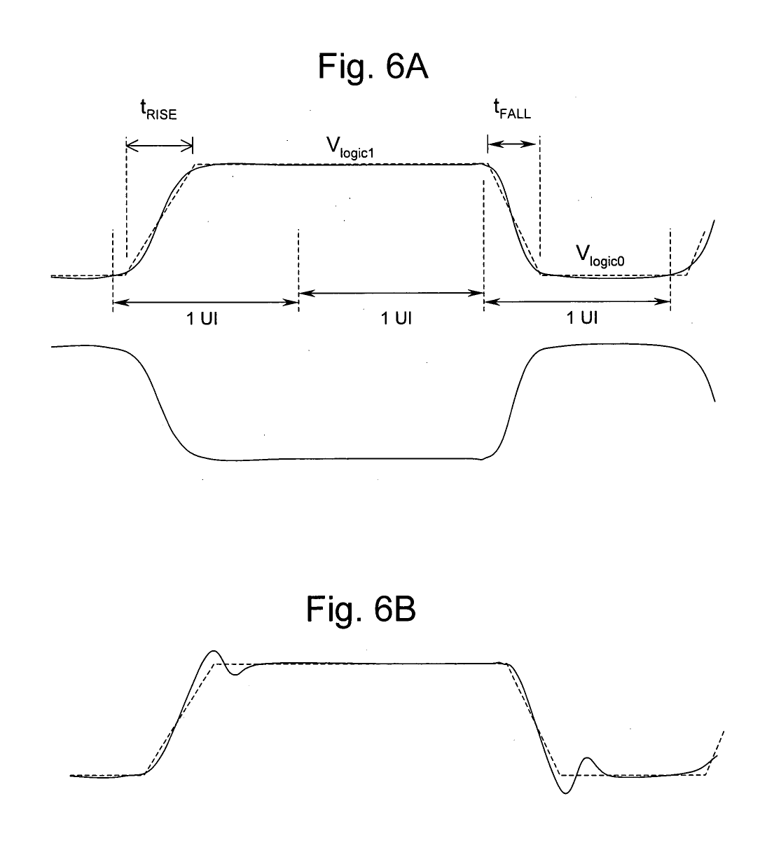

These transition times are first-order linear approximations. In reality, transitions will have at least second-order curves, but their 10%˜90% (rising) and 90%˜10% (falling) transitions times will typically be well correlated to the transition times for the piece-wise linear approximation used for the equations in these procedures, as illustrated in FIG. 6A and FIG. 6B. At the very least, this test will indicate the difference between the integrals of the rise and fall transitions.

Fourth, using the values of (V_{logic1}−V_{logic0}) from the first procedure, and (t_{RISE}−t_{FALL}), V_{4avg}, M, N, G₂ from this second procedure, the values of V_{logic0} and V_{logic1} can be calculated as follows:

$$\begin{matrix}{V}_{logic0} = {V}_{4 avg} - ( {V}_{logic1} - {V}_{logic0} ) ( M - {G}_{2} ( {t}_{RISE} - {t}_{FALL} ) / 2 ) / N \\ = 1.3050 - ( 0.2 ( 5 - 2 ( - 0.25 ) / 2 ) / 10 = 1.2\end{matrix}$$

V_{logic1}=V_{logic0}+(V_{logic1}−V_{logic0})=1.2+0.2=1.4 volts for the non-inverted signal.

Procedure for Measuring Waveform Rise Time and Fall Time, if Either is Greater than 1 UI

As stated in the description of the first procedure, the rise and fall transition times must be less than M unit intervals for the calculations to be accurate. Normally, transition times are less than one UI, so this is a trivial restriction. If t_{RISE} or t_{FALL} is greater than 1 UI, then both transition times can be determined using the following procedure, in which (T_{RISE}−T_{FALL}) can be positive or negative:

First, while the driver is transmitting a periodic N-bit pattern containing G isolated logic 1's, each separated by two or more logic 0's, measure the average output voltage V_{5avg}, via access resistors R_{A}. For example, for a 10-bit period with two isolated logic 1's, with t_{RISE}=1.1 UI and t_{FALL}=0.9 UI, the transmitted logic bits could be 1000010000, as shown for V₅ of FIG. 7; the average voltages measured would be (based on the calculated areas of the shaded region of V₅):

$$\begin{matrix}{V}_{5 avg} = {V}_{logic0} + G ( {V}_{logic1} - {V}_{logic0} ) ( {t}_{RISE} + {t}_{FALL} ) / ( 2 {Nt}_{{RISE}^{2}} ) \\ = 1.2 + 2 ( 0.2 ) ( 1.1 + 0.9 ) / ( 2 \times 10 \times {1.1}^{2} ) \\ = 1.23306 V\end{matrix}$$

Second, calculate values for t_{RISE} and T_{FALL}.

The equation for V_{avg5} can be solved for t_{RISE} as follows:

V_{5avg}=V_{logic0}+G(V_{logic1}−V_{logic0})(t_{RISE}+t_{FALL})/(2Nt_{RISE}²)

2N(V_{5avg}−V_{logic0})/(G(V_{logic1}−V_{logic0}))=(t_{RISE}+t_{FALL})/(t_{RISE}²)=R

Rt_{RISE}²−t_{RISE}−t_{FALL}=0

Using the standard solution for a quadratic equation, we solve for t_{RISE}:

t_{RISE}=[1±(1+4Rt_{FALL})^{0.5}]/(2R)

This equation produces two results (due to “±”), however, from various experiments, it can be determined that only the “+” solution need be used. The equation can then be re-written as:

4R²t_{RISE}²−8Rt_{RISE}+4R(t_{RISE}−t_{FALL})=0

Using the standard solution (again) for a quadratic equation to solve for t_{RISE}:

t_{RISE}=[8R±(64R²−64R³(t_{RISE}−t_{FALL}))^{0.5}]/(8R²)

Finally simplifying:

t_{RISE}=(1±(1−R(t_{RISE}−t_{FALL}))^{0.5})/R,

where, as stated earlier, R=(2N/G)(V_{5avg}−V_{logic0})/(V_{logic1}−V_{logic0})

For the example,

R=(2×10/2)(1.23306−1.2)/(0.2)=1.653

t_{RISE}=(1±(1−1.653(0.2))^{0.5})1.653=1.1

This equation produces two results (due to “±”), however, typically only the larger result is valid. Next, the value of t_{FALL} is calculated:

t_{FALL}=t_{RISE}−(t_{RISE}−t_{FALL})

t_{FALL}=1.1−(0.2)=0.9

(V_{logic1}−V_{logic0}) is obtained from the first procedure (whose result is independent of rise and fall times), and (t_{RISE}−t_{FALL}) is obtained from the second procedure. Thus all elements of these two equations are measured average values either from this procedure or derived from measured average values in the preceding procedures.

In summary, the three procedures described thus far, which can be performed in succession (and over-lapped—note that the V₂ and V₃ waveforms of FIG. 7 are the same), comprise only measurements of average voltages for different digital patterns. For data rates above 1 Gbit/second, the averaging can be performed with an RC low pass filter that has a corner frequency of one microsecond to permit a stable average voltage to be measured in less than a millisecond. A minimum of four different average voltages would need to be measured for each single-ended signal: two in the first procedure, one more in the second procedure (re-using the second step's voltage from the first procedure), and one more in the third procedure (reusing values calculated in the preceding procedures). Some of the voltages can also be measured differentially. These four DC measurements produce the values for three or four different AC parameters: V_{logic0}, V_{logic1}, t_{RISE}−t_{FALL}, and (if either is larger than 1 UI) t_{RISE} and t_{FALL}.

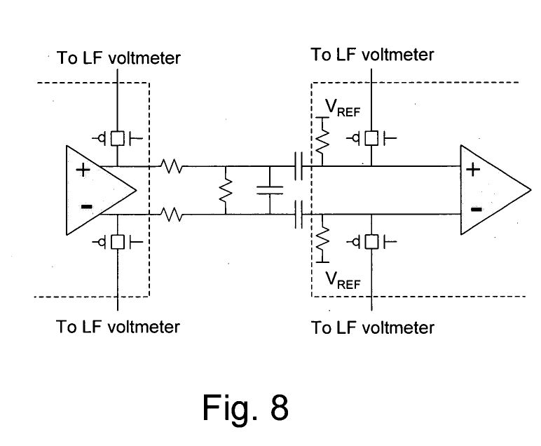

These procedures can be used to test these parameters for any circuit that conveys DC levels, including some analog circuits. For a circuit that does not convey DC levels, such as the capacitor-coupling shown in FIG. 8, the average received voltage for any digital pattern will be constant (and equal to the applied bias voltage, V_{REF}) for all patterns; however the average voltage will change briefly when a new pattern is introduced, and this may be long enough to make a measurement, i.e. the high pass corner frequency must be much lower than the reciprocal of the measurement time. For example, if the high-pass corner frequency is 10 hertz, then an average voltage for a new pattern can be measured meaningfully in 1 millisecond (whose reciprocal is 1000 hertz) before the voltage settles to its constant bias voltage.

By dividing the deduced logic levels of a circuit's output by the values deduced for its input, the linear voltage gain of the circuit can be deduced. Any increase in the deduced transition times can be used to calculate the circuit's frequency response, and any decrease in only the deduced transition times can be used to calculate the non-linear voltage gain (linear gain followed by hard limiting).

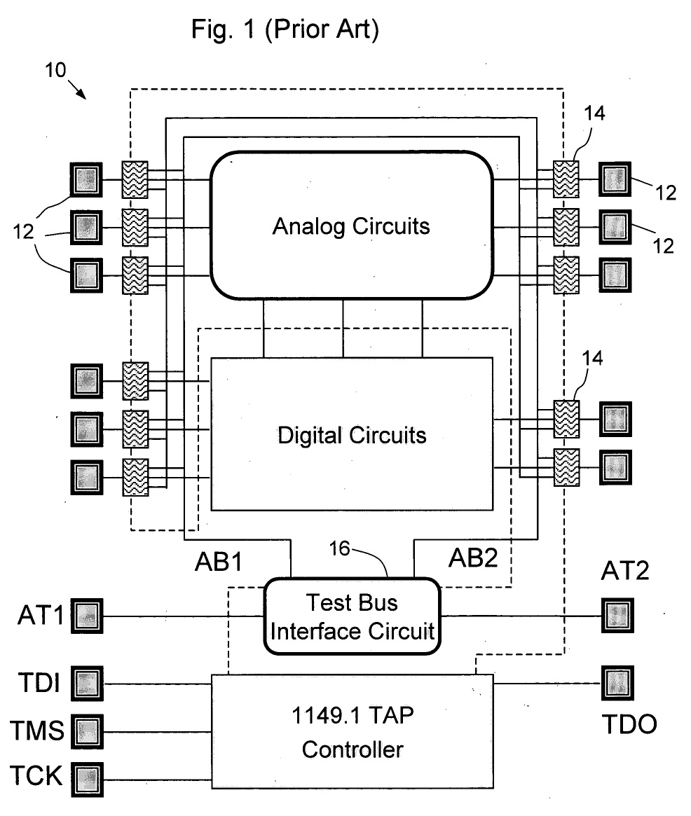

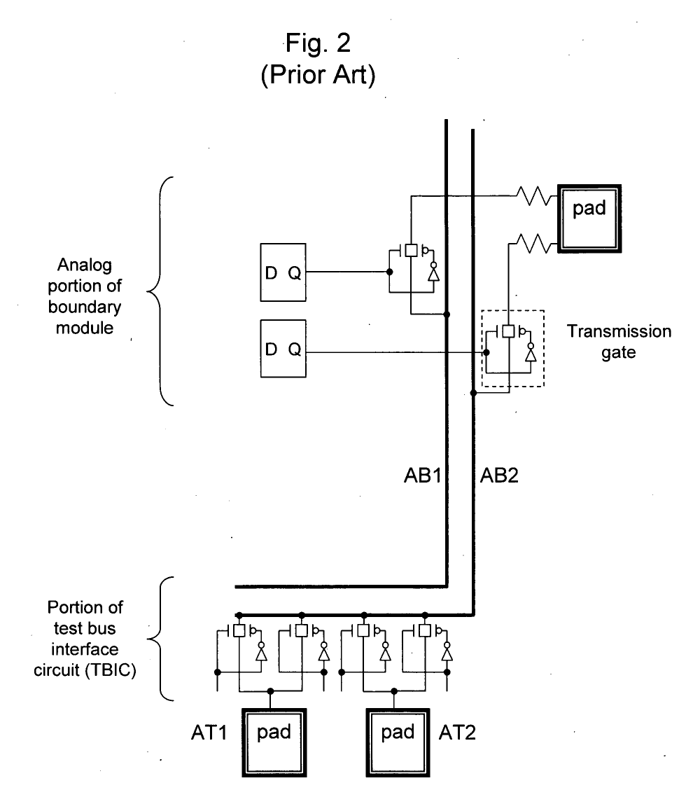

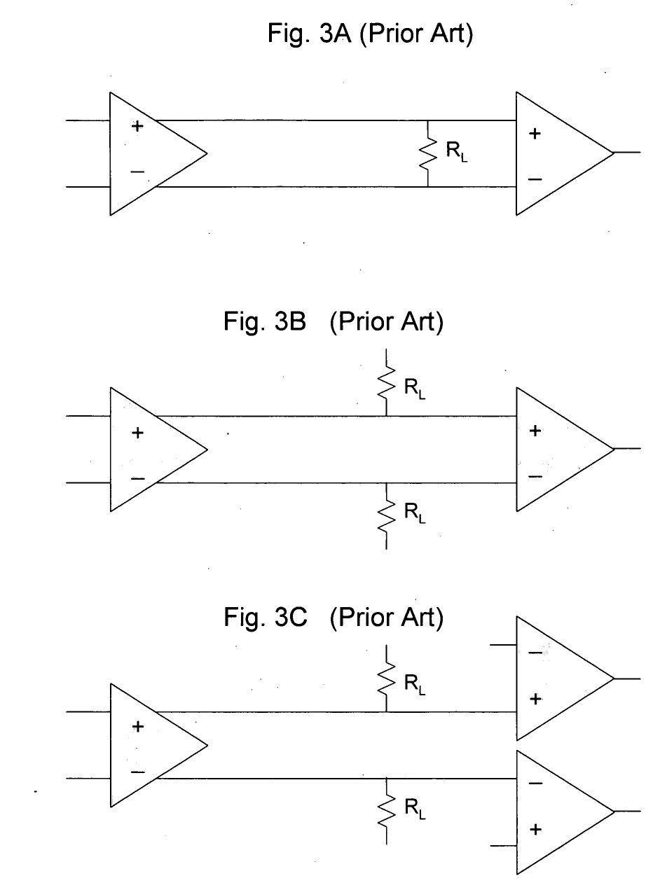

The average voltages may be measured via an analog bus, for example like that shown in FIG. 1 and FIG. 2 for the 1149.4 standard. This also permits high speed pins of an integrated circuit to be tested for basic AC parameters without physically connecting to the pin of the IC, and thus reducing the cost of test access. Some output drivers require a termination resistor to produce meaningful logic levels, and some also require a load capacitance to produce meaningful transition times. A resistor and capacitor can be connected physically close to output pins so that transmission line effects are avoided, and then the logic levels and transition times can be measured via the on-chip analog bus. Alternatively, automatic test equipment can connect to the high speed pins via the previously described access resistors so that transmission line effects are avoided.

The method of the present invention can be applied to the determination of logic voltages for signals that have more than two voltage levels by changing selected bits and measuring the resultant change in average voltage.

For all of the tests described herein, test limits for the values calculated may be determined by characterizing known good devices and known bad devices. Test limits may be pre-calculated for the last measurement in each procedure so that a circuit under test can be immediately passed or failed after the measurement.

The important capability provided by the present invention is the ability to quickly and accurately measure at-speed logic levels without needing high frequency access or high frequency measurement capability. Prior art circuits and methods are not able to achieve this accuracy without requiring very accurate passive components and/or very high bandwidth test access.

Although the present invention has been described in detail with regard to preferred embodiments and drawings of the invention, it will be apparent to those skilled in the art that various adaptions, modifications and alterations may be accomplished without departing from the spirit and scope of the present invention. Accordingly, it is to be understood that the accompanying drawings as set forth hereinabove are not intended to limit the breadth of the present invention, which should be inferred only from the following claims and their appropriately construed legal equivalents.

We claim:

1. A method for deducing parameters of data signals, comprising:
generating data signals using predetermined data sequences;
measuring average voltage of each said data signals; and
deducing said parameters from said average voltages.

2. A method as defined in claim 1, said parameters being logic voltages and rise and fall times.

3. A method as defined in claim 1, when said parameters are the difference between two logic levels, said measuring average voltages of each said data signals, including:
(a) measuring average voltage for a periodic pattern containing a number of consecutive same-value logic values;
(b) measuring average voltage for a pattern containing a different number of consecutive same-value logic values; and
said deducing said parameters including:
(c) performing a calculation based on measured average voltages to deduce the difference between two logic levels.

4. A method as defined in claim 3, further including, performing said calculation before performing step (b); and, after performing step (b), comparing the average voltage measured in step (b) to an expected average voltage that would produce an acceptable difference between said two logic levels.

5. A method as defined in claim 1, wherein when said parameters are the difference between effective rise and fall transition times, said measuring average voltages including:
(a) measuring average voltage for a periodic pattern containing a number of consecutive same-value logic values;
(b) measuring average voltage for a pattern in which the number of consecutive same-value logic values are split in two or more groups of same-value logic values; and
said deducing said parameters including:
(c) performing a calculation based on measured average voltages to obtain the difference between effective rise and fall transition times.

6. A method according to claim 5, further including, performing said calculation before step (b); and after performing step (b), comparing the average voltage measured in step (b) to an expected average voltage that would produce an acceptable difference between effective rise and fall transition times.

7. A method as defined in claim 1, wherein when said parameters are rise and fall transition times, said measuring average voltages includes:
(a) measuring average voltage for a periodic pattern containing a number of consecutive same-value logic values;
(b) measuring average voltage for a pattern containing a different number of consecutive same value logic values;
(c) measuring average voltage for a pattern in which said number of consecutive same-value logic values is split into two or more groups of same-value logic values;
(d) measuring average voltage for a pattern containing one or more isolated logic values surrounded by the opposite logic value; and
said deducing said parameters including:
(e) performing a calculation based on measured average voltages to obtain rise and fall transition times.

8. A method as defined in claim 7, further including performing said calculation before step (d) and, after performing step (d), comparing the average voltage measured in step (d) to an expected average voltage that would produce acceptable rise and fall transition times.

9. A method of testing a digital circuit, comprising deducing parameters as defined in claim 1 and comparing deduced parameter values against expected parameter values to determine whether said digital circuit passes or fails.

10. A method of testing an analog circuit, comprising deducing parameters as defined in claim 1 and comparing deduced parameter values against expected parameter values to determine whether said analog circuit passes or fails.

11. A method as defined in claim 1, further including:
comparing deduced logic voltages and rise and fall times values of a circuit output signal to deduced logic voltages and rise and fall times values of a circuit input signal to determine circuit gain or frequency response.
